(19) United States
(12) Patent Application Publication
(10) Pub. No.: US 2013/0003281 A1
(43) Pub. Date: Jan. 3, 2013

(54) ELECTRONIC DEVICE

(75) Inventor: Wen-Cheng Chen, Taipei City (TW)

(73) Assignee: COMPAL ELECTRONICS, INC., Taipei City (TW)

(21) Appl. No.: 13/174,803

(22) Filed: Jul. 1, 2011

(51) Int. Cl. G06F 1/16; H05K 5/00; H05K 7/00

(52) U.S. Cl. 361/679.21; 361/807; 361/752

(57) ABSTRACT

An electronic device including at least one connecting member, a display unit and a host is provided in the present invention. The connecting member has a first fixing section, a second fixing section and a third fixing section. The display unit includes a front bezel and a panel, and the panel is fixed to the connecting member through the first fixing section. The host is fixed to the connecting member through the second fixing section or the third fixing section depending on the size of the display unit. The connecting member and the panel are disposed between the front bezel and the host. The assembling of the host and the display unit is flexible by using the connecting member.

### BACKGROUND OF THE INVENTION

1. Field of the Invention

The present invention generally relates to an electronic device, and more particularly to an electronic device having a host and a display unit.

2. Description of Related Art

In this information society, people increasingly depend on electronic products. The electronic products such as all-in-one personal computers (AIO PCs), tablet personal computers (tablet PCs) or laptops are widely used in daily life. Display and host are assembled together in all-in-one computers to meet the requirements of few parts in components, compact in size and low manufacturing costs.

In the manufacturing process, module production is often needed to lower the manufacturing costs and higher the manufacturing efficiency. However, in nowadays manufacturing of all-in-one computer, it is lack of some flexibility or variety especially in the assembling of hosts and displays.

### SUMMARY OF THE INVENTION

Accordingly, the present invention is directed to an electronic device in which the assembly of host and display is flexible.

The present invention provides an electronic device including a host, at least one connecting member and a display unit. The connecting member has a plurality of first fixing section, a second fixing section and a third fixing section. The display unit has a front bezel and a panel. The panel is fixed to the connecting member through the first fixing section. The host is fixed to the connecting member through the second fixing section or the third fixing section depending on the size of the display unit. Herein the panel and the connecting member are disposed between the front bezel and the host.

According to an embodiment of the present invention, the connecting member includes a first plate and a second plate. The first fixing section is formed on the first plate. The second plate is connected to the first plate, wherein the second fixing section and the third fixing section are formed on the second plate.

According to an embodiment of the present invention, the panel has a side and a rear surface. The first plate is fixed to the side and thereby the second plate is substantially parallel to the rear surface.

According to an embodiment of the present invention, the number of the at least one connecting member is two and the connecting members are fixed to two sides of the panel respectively.

According to an embodiment of the present invention, the distance between the second fixing sections of the connecting members fixed to the display unit in one size is the same as the distance between the third fixing sections of the connecting members fixed to the display unit in another size.

According to an embodiment of the present invention, the electronic device further includes a back cover. The back cover is fixed to the host and the host is located between the display unit and the back cover.

According to an embodiment of the present invention, the connecting member is adapted to fix with the display units in different sizes respectively while being fixed with the same-size hosts.

According to an embodiment of the present invention, the host includes a board and at least one electronic component. The connecting member is fixed to the board. The at least one electronic component is disposed on the board.

According to an embodiment of the present invention, the electronic device is an all-in-one computer.

According to an embodiment of the present invention, the panel is fixed to the connecting member in a first fixing direction and the host is fixed to the connecting member in a second fixing direction.

According to an embodiment of the present invention, the first fixing direction and the second fixing direction are substantially orthogonal.

According to an embodiment of the present invention, the display unit further includes a back frame fixed to the front bezel and the panel is contained in a space defined by the back frame and the front bezel.

According to an embodiment of the present invention, the first fixing section, the second fixing section and the third fixing section are fixing holes.

According to an embodiment of the present invention, the first fixing section is a fixing hole, and the second fixing section and the third fixing section form a fixing slot.

In view of the above, according to the embodiments of the present invention, through the different combinations of fixing holes formed on the connecting member, the display units with different sizes are enabled to fix to the host through the connecting member. And thus, the assembling is flexible and manufacturing costs can be reduced in all-in-one computer manufacturing.

In order to make the above features and advantages of the present invention comprehensible, embodiments are described in detail below with the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates an electronic device according to an embodiment of the present invention.

FIG. 2 schematically illustrates an exploded view of a display unit of the electronic device in FIG. 1.

FIG. 3 schematically illustrates an exploded view of the electronic device in FIG. 1.

FIG. 4 schematically illustrates partial components of the electronic device in FIG. 1.

FIG. 5 schematically illustrates the connecting member of the electronic device in FIG. 1.

FIG. 6 schematically illustrates the connecting member of the electronic device according to another embodiment of present invention.

FIG. 7 illustrates the host in FIG. 1 connecting to a larger display.

FIG. 8 schematically illustrates an exploded view of the electronic device in FIG. 7.

FIG. 9 schematically illustrates partial components of the electronic device in FIG. 7.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The figures are not drawn to scale and they are provided merely to illustrate the present invention. Several aspects of the invention are described below with reference to example applications for illustration. It should be understood that numerous specific details, relationships and methods are set forth to provide a full understanding of the invention. The present invention may be embodied in many different forms and should not be construed as limited to the embodiments set forth herein. For example, the present invention can be embodied as a method or a system.

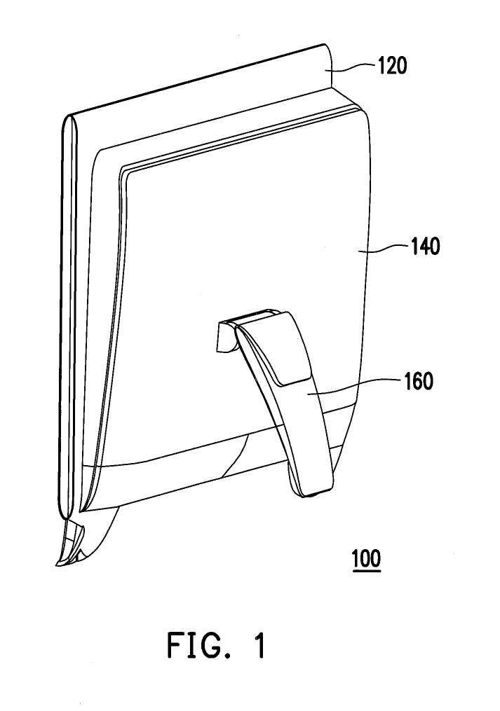

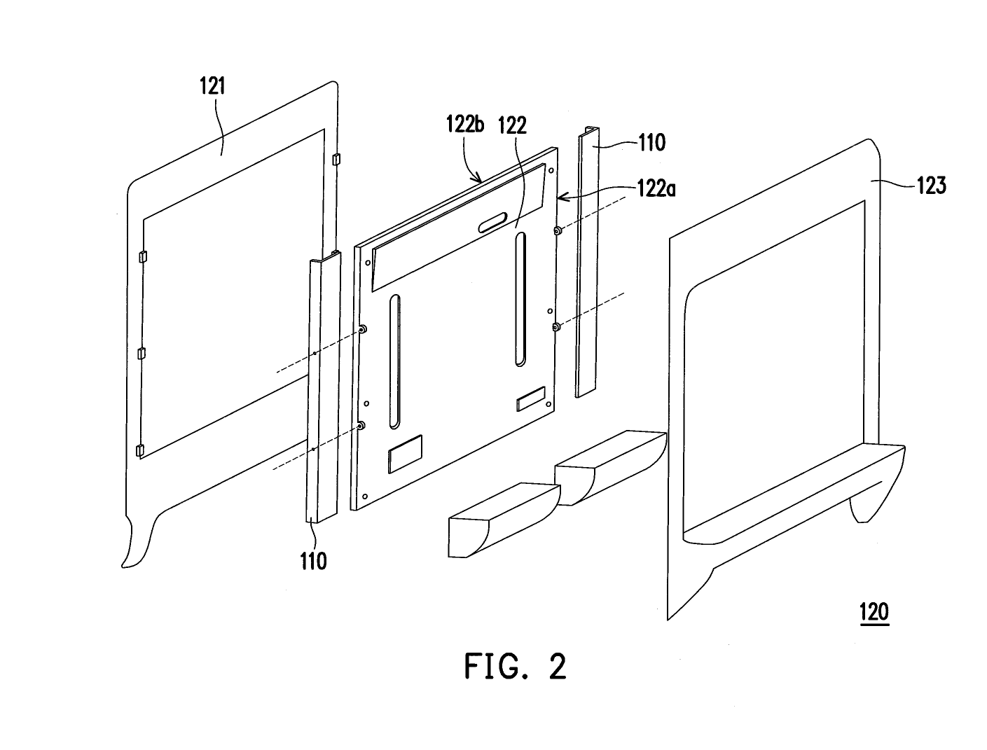

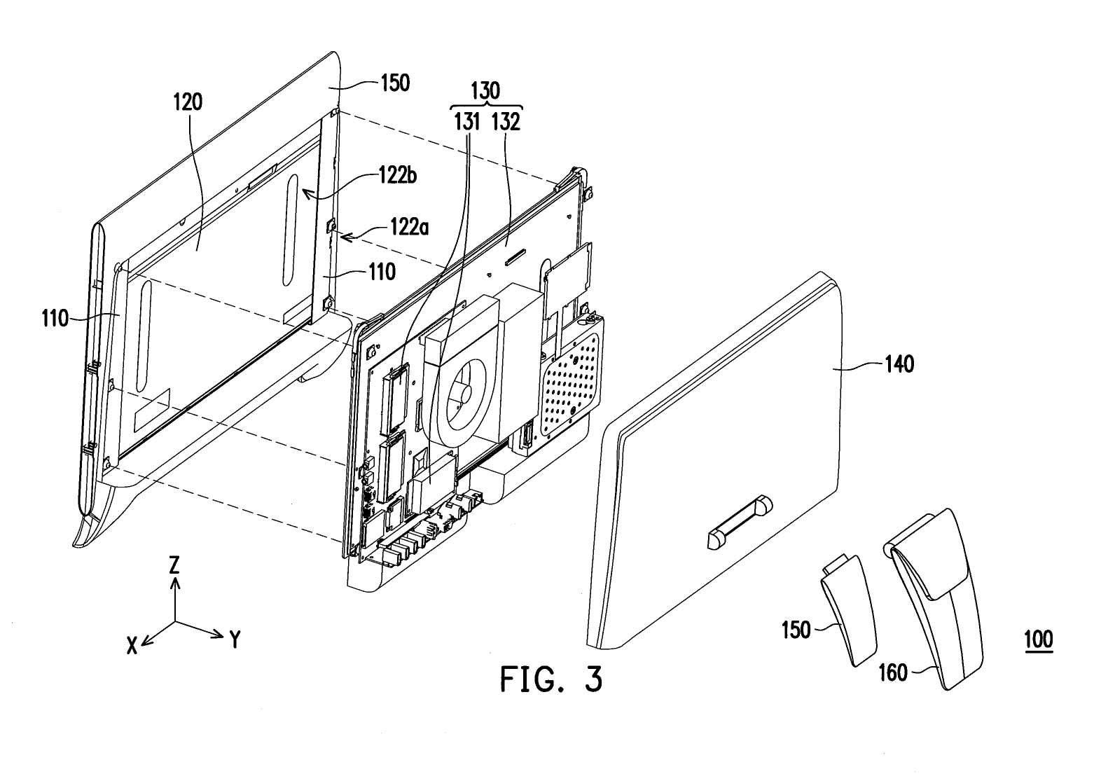

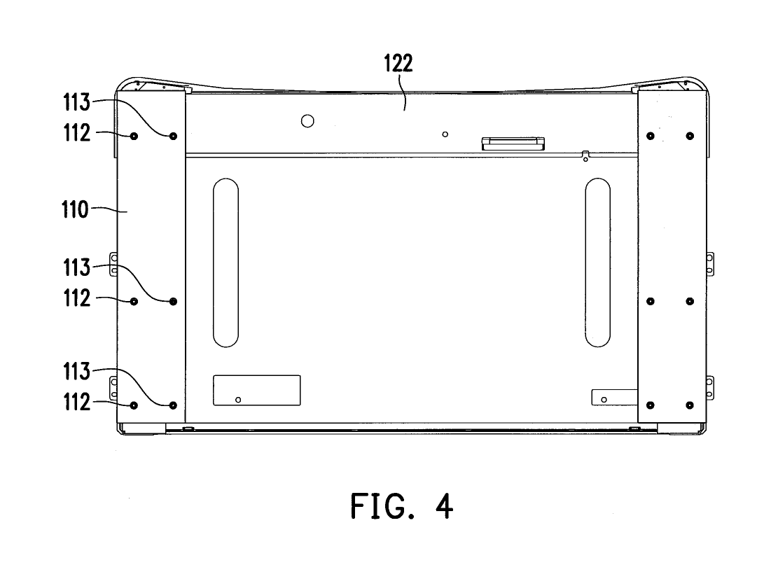

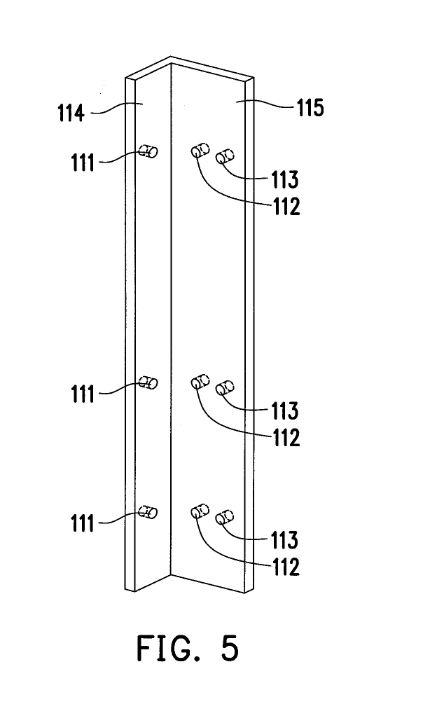

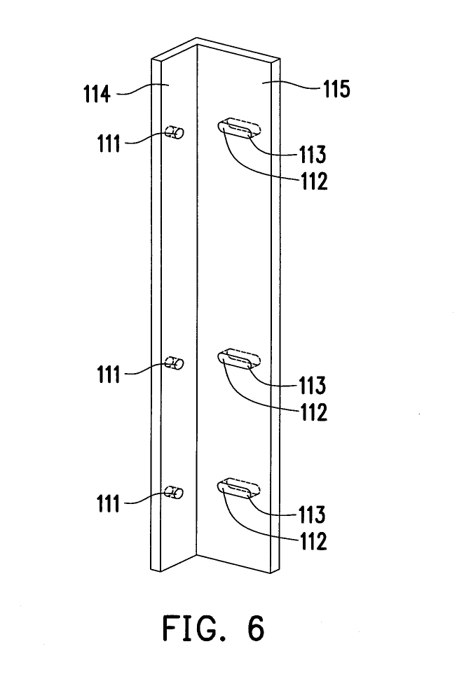

FIG. 1 illustrates an electronic device according to an embodiment of present invention. FIG. 2 schematically illustrates an exploded view of a display unit of the electronic device in FIG. 1. FIG. 3 schematically illustrates an exploded view of the electronic device in FIG. 1. FIG. 4 schematically illustrates partial components of the electronic device in FIG. 1. FIG. 5 schematically illustrates the connecting member of the electronic device in FIG. 1. FIG. 6 schematically illustrates the connecting member of the electronic device according to another embodiment of present invention. Please refer to FIG. 1 to FIG. 5. In the embodiment, an electronic device 100 includes at least one connecting member 110 (showing two), a display unit 120 and a host 130. The electronic device 100 is, for example, an all-in-one computer. The host 130 and the display unit 120 of the electronic device 100 are assembled by using at least one connecting member 110. The connecting member 110 has a first fixing section 111, a second section 112 and a third fixing section 113. In an embodiment, as shown in FIG. 6, the first fixing section of the connecting member 110 can be fixing holes 111, and the second fixing section 112 and the third fixing section 113 can form a slot, for example. And the host 130 is fixed to the slot formed by the second fixing section 112 and the third fixing section 113 by using bolts sliding in the slot and being fixed to fixing ends (not shown), for example. Or threads can be configured within the slot and the host 130 can be fixed to the slot by using screws. In another embodiment, the first fixing section, the second fixing section and the third fixing section of the connecting member 110 can all be fixing holes as shown in FIG. 5. In subsequent descriptions, the term “fixing section” is used interchangeably with the term “fixing holes”.

Referring now to FIG. 2 to FIG. 5, the connecting member 110 is fixed to the display unit 120 through the first fixing holes 111. The display unit 120 has a front bezel 121, a panel 122 and a back frame 123. The back frame 123 is fixed to the front bezel 121 and the panel 122 is contained in a space defined by the back frame 123 and the front bezel 121. The panel 122 is fixed to the connecting member 110 through the first fixing holes 111. The panel 122 and the connecting member 110 are disposed between the front bezel 121 and the host 130. The host 130 is fixed to the connecting member 110 through the second fixing holes 112. The third fixing holes 113 are used when the host 130 is connected to a display unit with different size, for example a larger display unit. The host 130, connecting to a larger display unit through the third fixing holes 113 of the connecting member 110, is described in detail accompanying with figures as follows.

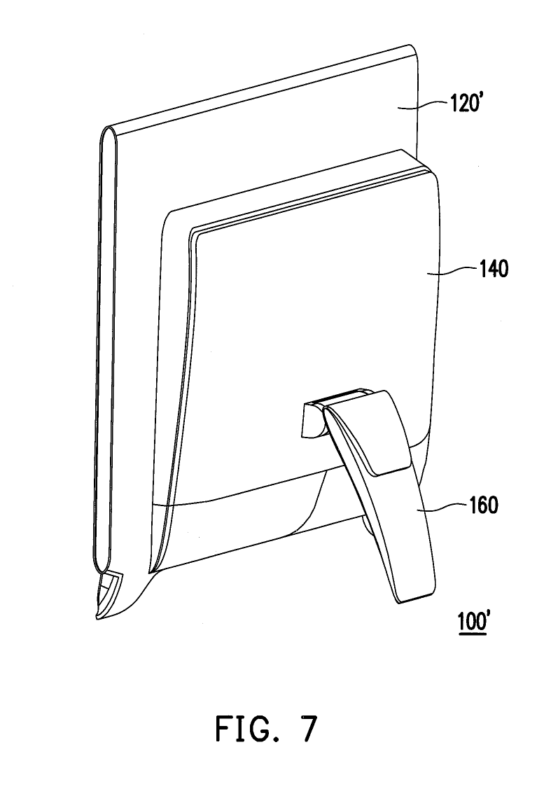

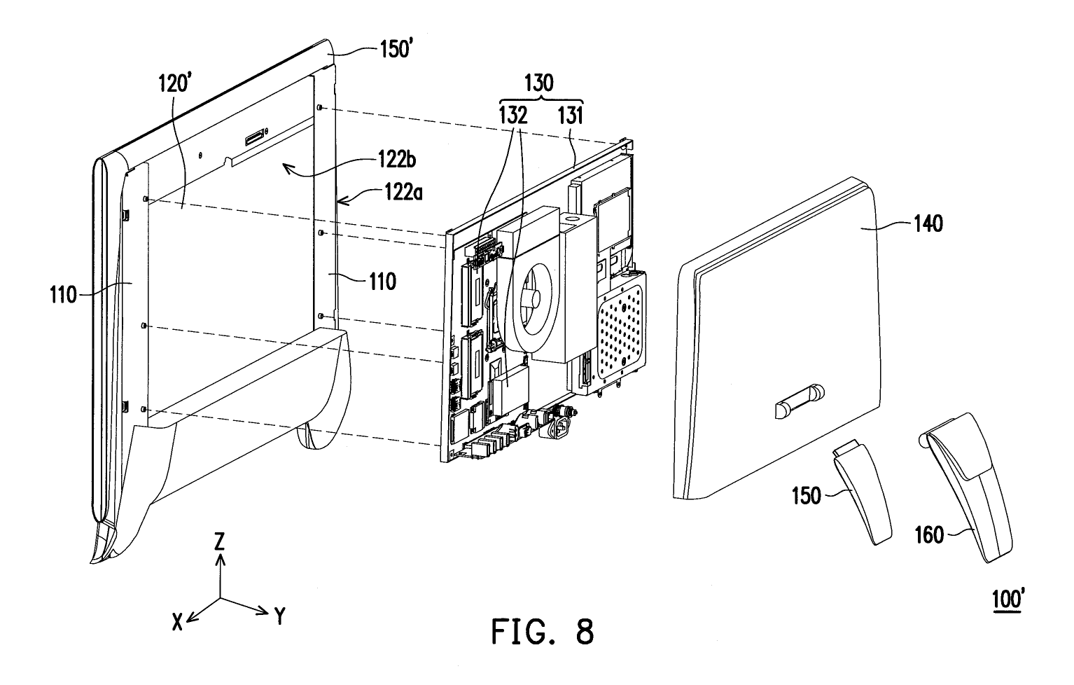

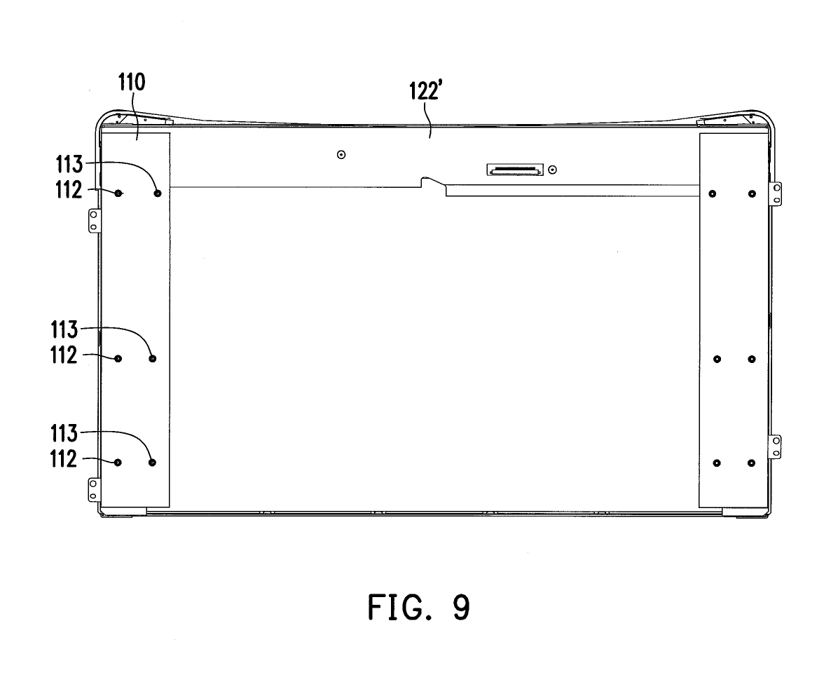

FIG. 7 illustrates the host in FIG. 1 connecting to a larger display unit. FIG. 8 schematically illustrates an exploded view of the electronic device in FIG. 7. FIG. 9 schematically illustrates partial components of the electronic device in FIG. 7. Please refer to FIG. 5, FIG. 7 to FIG. 9. In the embodiment, an electronic device 100′ includes the connecting members 110, a display unit 120′ and the host 130. The host 130 and the connecting members 110 are the same as that shown in FIG. 1 to FIG. 5, and the display unit 120′ is larger than the display unit 120 shown in FIG. 1 to FIG. 4. The host 130 and the display unit 120′ of the electronic device 100′ are assembled by using the connecting member 110. The connecting member 110 is fixed to panel 122′ of the display unit 120′ through the first fixing holes 111. The host 130 is fixed to the connecting member 110 through the third fixing holes 113.

With such configuration, the hosts 130 with the same dimension can be assembled with the display units 120 and 120′ with different dimensions through the connecting member 110, so that the assembling between the hosts 130 and the display units 120 and 120′ can be flexible. Extra group of fixing holes can be formed on the connecting member according to the requirement of assembling the desired different sizes of display units to the host.

The structure of the connecting member 110 above mentioned is described in detailed as follows. As shown in FIG. 5, the connecting member 110 includes a first plate 114 and a second plate 115 connected to the first plate 114. The first fixing holes 111 are formed on the first plate 114, and the second fixing holes 112 and the third fixing holes 113 are formed on the second plate 115. Referring to FIG. 1 to FIG. 5, the panel 122 has a side 122a and a rear surface 122b. The first plate 114 is fixed to the side 122a through the first fixing holes 111, and after the connecting member 110 is fixed to the panel 122, the second plate 115 is substantially parallel to the rear surface 122b. Similarly, referring to FIG. 5, FIG. 7 to FIG. 9, the first plate 114 is fixed to the side 122a through the first fixing holes 111, and after the connecting member 110 is fixed to the panel 122′, the second plate 115 is substantially parallel to the rear surface 122b. In the embodiment, the order of assembling the host 130 and the display unit 120 is, after the first plate 114 is fixed to the side 122a of the panel 122 (or 122′), the panel 122 (or 122′) and the front bezel 121 and the back frame 123 are assembled to from the display unit 120 (or 120′) with the connecting member 110 therein, and then the host 130 is fixed to the second plate 115. In detail, the panel 122 is fixed to the connecting member 110 in a first fixing direction (X direction as shown in FIG. 3 and FIG. 8) and the host 130 is fixed to the connecting member 110 in a second direction (Y direction as shown in FIG. 3 and FIG. 8), for example. It is to be noted that fixing elements such as screws or the like are used to fix the connecting member 110 to the panel 122 (or 122′) and the host 130.

The number of fixing holes of each group of fixing holes is not limited in present invention. FIG. 5 shows three fixing holes are included in each group of fixing holes as an example in the embodiment. Any suitable number of fixing holes can be formed on the connecting member in other embodiments as required.

In the embodiment, the material of the connecting member 110 can be either plastic or metal. If the material of the connecting member 110 is plastic, then it can be integrally formed. However, it is to be understood that the present invention is not limited thereto.

As shown in FIG. 3 and FIG. 8, the two connecting members 110 are fixed to two sides 122a of the panel 122 of the display unit 120 (or 120′) respectively for firmly assembling the host 130 on the display unit 120 (or 120′). It is to be noted that the distance between the second fixing holes 112 of the connecting members 110 fixed to the display unit in one size (for example the display unit 120) is the same as the distance between the third fixing holes 113 of the connecting members 110 fixed to the display unit in another size (for example the display unit 120′). Besides, the host 130 includes a board 131 and at least one electronic component 132. The connecting member 110 is fixed to the board 131 and the at least one electronic component 132 is disposed on the board 131. The electronic device 100 (or 100′) further includes a back cover 140. The back cover 140 is fixed to the host 130 and covers the connecting member 110. The host 130 is located between the display unit 120 (or 120′) and the back cover 140. The back cover 140 can prevent the elements of the host 130 being contaminated or damaged from dust, slops or other unexpected materials. In addition, the electronic device 100 may further include a hinge 150 and a stand 160. An angular adjustment can be done to the electronic device 100 through the hinge 150 while it is located on a table, for example. The stand 160 is to facilitate the electronic device 100 stands stably.

In summary, according to the embodiments of the present invention, through the different combinations of fixing sections formed on the connecting member, the display unit with different sizes is enabled to fix to the host. And thus, the assembling is flexible and manufacturing costs can be reduced in all-in-one computer manufacturing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device, comprising:
at least one connecting member having a first fixing section, a second fixing section and a third fixing section;
a display unit having a front bezel and a panel, the panel being fixed to the connecting member at the first fixing section; and
a host fixed to the connecting member at the second fixing section or the third fixing section depending on a size of the display unit,
wherein the panel and the connecting member are disposed between the front bezel and the host.

2. The electronic device according to claim 1, wherein the connecting member comprises:
a first plate, wherein the first fixing section is formed on the first plate; and
a second plate connected to the first plate, wherein the second fixing section and the third fixing section are formed on the second plate.

3. The electronic device according to claim 2, wherein the panel has a side and a rear surface, and the first plate is fixed to the side and thereby the second plate is substantially parallel to the rear surface.

4. The electronic device according to claim 1, wherein the number of the at least one connecting member is two and the connecting members are fixed to two sides of the panel respectively.

5. The electronic device according to claim 4, wherein the distance between the second fixing sections of the connecting members fixed to the display unit in one size is the same as the distance between the third fixing sections of the connecting members fixed to the display unit in another size.

6. The electronic device according to claim 1, further comprising:
a back cover fixed to the host, wherein the host is located between the display unit and the back cover.

7. The electronic device according to claim 1, wherein the connecting member is adapted to fix with the display units in different sizes respectively while being fixed with the same-size hosts.

8. The electronic device according to claim 1, wherein the host comprising:
a board, wherein the connecting member is fixed to the board; and
at least one electronic component disposed on the board.

9. The electronic device according to claim 1, wherein the electronic device is an all-in-one computer.

10. The electronic device according to claim 1, wherein the panel is fixed to the connecting member in a first fixing direction and the host is fixed to the connecting member in a second fixing direction.

11. The electronic device according to claim 10, wherein the first fixing direction and the second fixing direction are substantially orthogonal.

12. The electronic device according to claim 1, wherein the display unit further comprises a back frame fixed to the front bezel and the panel is contained in a space defined by the back frame and the front bezel.

13. The electronic device according to claim 1, wherein the first fixing section, the second fixing section, and the third fixing section are fixing holes.

14. The electronic device according to claim 1, wherein the first fixing section is a fixing hole, and the second fixing section and the third fixing section form a fixing slot.
